(19) United States
(12) Patent Application Publication
(10) Pub. No.: US 2005/0205889 A1
(43) Pub. Date: Sep. 22, 2005

(54) Light emitting diode package with high power

(76) Inventor: Hsing Chen, Kukou Township (TW)

Correspondence Address: PRO-TECTOR INTERNATIONAL SERVICES, 20775 NORADA CT., SARATOGA, CA, 95070, US

(21) Appl. No.: 11/066,526

(22) Filed: Feb. 22, 2005

(30) Foreign Application Priority Data
Mar. 16, 2004 (TW) 093107060

(51) Int. Cl. H01L 29/24

(52) U.S. Cl. 257/100

(57) ABSTRACT

A light emitting diode package includes a substrate, a conductive material, a LED chip, and a lens. The substrate has an upper surface formed with a P-electrode and a N-electrode, a lower surface formed with a cavity, and a through hole penetrating the substrate from the upper surface to the lower surface. The conductive material is filled within the cavity of the substrate. The LED chip is located within the through hole of the substrate and is mounted on the conductive material, and is electrically connected to the P-electrode and the N-electrode of the substrate. The lens is covered over the LED chip.

### BACKGROUND OF THE INVENTION

1. Field of the invention

The invention relates to a light emitting diode package, and more particularly to a light emitting diode package that is easy to be fabricated and capable of increasing the effective of heat dissipation.

2. Description of the Related Art

The light emitting diode (LED) has the advantages of being electricity-saving, high reliability, recyclable, and safety. Thus it has been used widely in applications such was various indicators and various light sources. Recently light emitting diode for RGB(red, green and blue) colors having ultra-high luminance and high efficiency have been developed, and large screen LED displays using these light emitting diode have been put into use. The LED display can be operated with less power and has such good characteristics as light weight and long life, and is therefore expected to be more widely use in the future.

Please referring to FIG. 1, a conventional light emitting diode package includes a first heat sink 11, a second heat sink 12, an insulation body 30, electrodes 31,32, a LED chip 20, a first lens 41, and a second lens 42. The first heat sink 11 is mounted to the second heat sink 12. The LED chip 20 is located on the heat sink 11. The heat energy generated by LED chip 20 may be dissipated through the first heat sink 11 and the second heat sink 12. But, the manufacturing processes are inconveniently.

Furthermore, the electrodes 31, 32 of the insulation body 30 are electrically connected to a printed circuit board by wires, thus, the manufacturing processes are inconveniently.

It is very also important how to obtain high heat dissipation LED. In particular, a white light emitting diode may be produced to generate high heat energy. Therefore, the heat dissipation effect is very important.

### SUMMARY OF THE INVENTION

An objective of the invention is to provide a light emitting diode package that the lifetime of the product can be prolonged effectively.

Another objective of the invention is to provide a light emitting diode package that the brightness of the product can be increased.

Another objective of the invention is to provide a light emitting diode package that the size of the LED can be produced to be lighter, thinner, and smaller than that of the conventional LED.

To achieve the above-mentioned objective, the invention includes a substrate, a conductive material, a LED chip, and a lens. The substrate has an upper surface formed with a P-electrode and a N-electrode, a lower surface formed with a cavity, and a through hole penetrating the substrate from the upper surface to the lower surface. The conductive material is filled within the cavity of the substrate. The LED chip is located within the through hole of the substrate and is mounted on the conductive material, and is electrically connected to the P-electrode and the N-electrode of the substrate. The lens is covered over the LED chip.

Therefore, the light generated from LED chip 4 can be refracted, so that the brightness of the light emitting diode may be promoted, and can be produced to be lighter, thinner, and smaller.

### BRIEF DESCRIPTION OF THE DRAWINGS

FIG. 1 is an explosion view showing a conventional light emitting diode package.

FIG. 2 is an explosion view showing a light emitting diode package of the present invention.

FIG. 3 is the cross-sectional schematic illustration showing a light emitting diode package of the present invention.

FIG. 4 is the cross-sectional schematic illustration showing the lens of a light emitting diode package of the present invention.

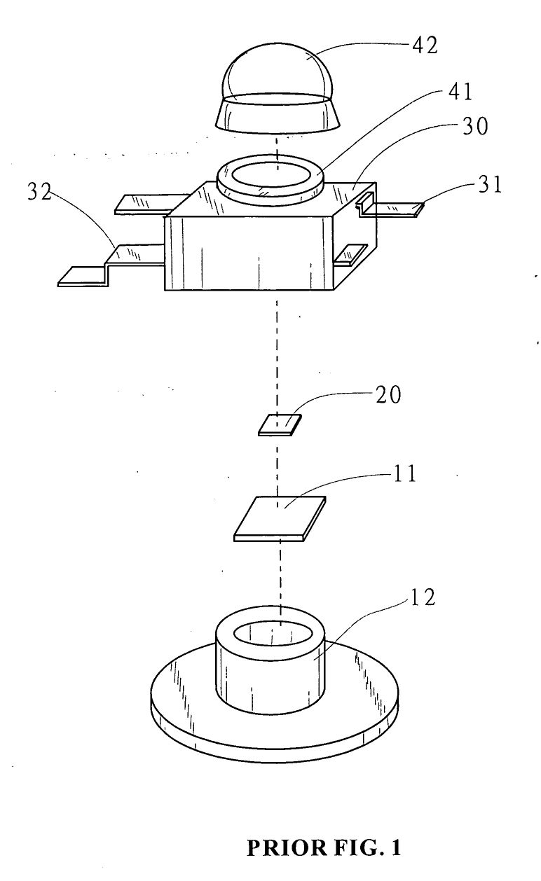

### DETAILED DESCRIPTION OF THE INVENTION

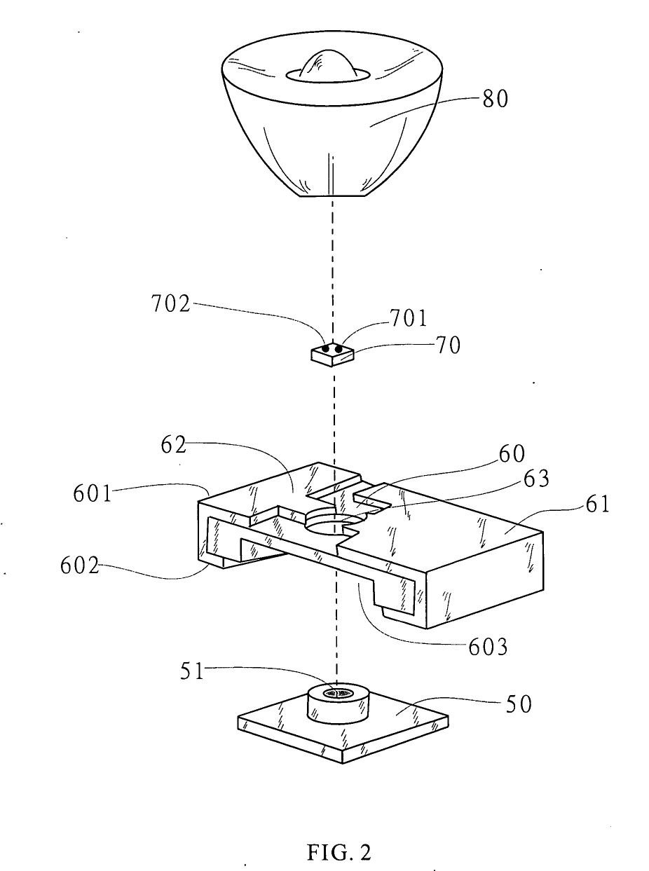

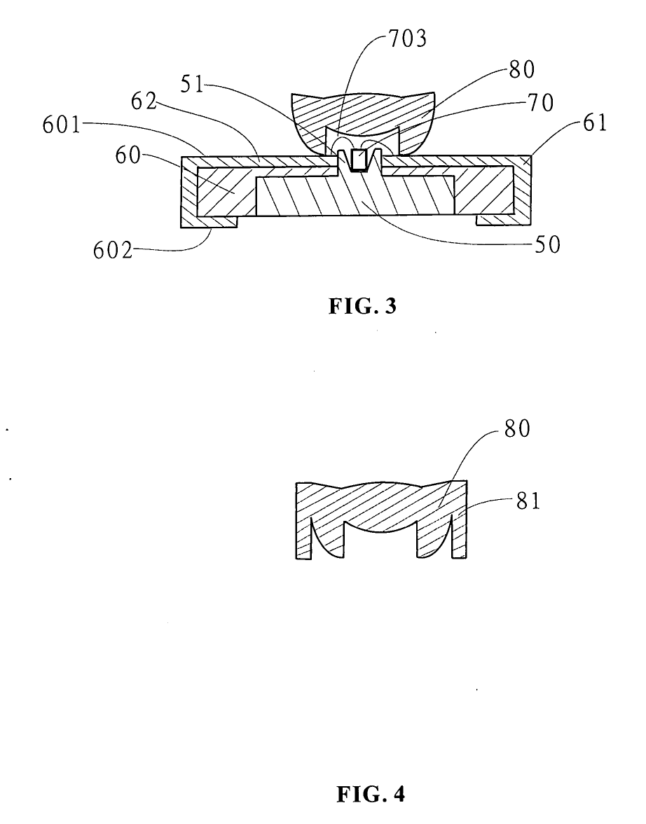

Please refer to FIG. 2 and FIG. 3. A light emitting diode package of the present invention includes a substrate 60, an LED chip 70, a conductive material 50, and a lens 80.

The substrate 60 has an upper surface 601 formed with a P-electrode 61 and a N-electrode 62, a lower surface 602 formed with a cavity 603, and a through hole 63 penetrating the substrate 60 from the upper surface 601 to the lower surface 602. The P-electrode 61 and N-electrode 62 of the substrate 60 are extended from the upper surface 601 to the lower surface 602 of the substrate 60, so that the P-electrode 61 and a N-electrode 62 of the substrate 60 may be mounted to a printed circuit board by SMT.

The conductive material 50 is formed of golden or silver or copper or aluminum or tin or alloy, which is filled within the cavity 603 of the substrate 60. The top end of the conductive material 50 is formed with a trough 51 for locating the LED chip 70. Therefore, the heat energy generated by LED chip 70 when applied a higher current can be dissipated, so that the durability and lifetime of the light emitting diode can be prolonged effectively.

The LED chip 70 is formed with a P-electrode 701 electrically connected to the P-electrode 61 of the substrate 60 by wire 703 and a N-electrode 702 electrically connected to the N-electrode 62 of the substrate 60 by wire 703. The LED chip 70 is located within the through hole 60 of the substrate 60 and is mounted on the trough 51 of the conductive material 50.

Please refer to FIG. 4. The lens 80 is formed with a cylinder 81 for mounting on the upper surface 601 of the substrate 60 to cover over the LED chip 70. The lens 80 may focus the light emitted from the LED chip 70, so that the brightness of the light emitting diode may be promoted.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded to the broadest interpretation so as to encompass all such modifications.

1. A light emitting diode package comprising:
a substrate having a upper surface formed with a P-electrode and a N-electrode, a lower surface formed with a cavity, and a through hole penetrating the substrate from the upper surface to the lower surface;
a conductive material filled within the cavity of the substrate;
at least an LED chip located within the through hole of the substrate and mounted on the conductive material, and electrically connected to the P-electrode and the N-electrode of the substrate;
a lens covered on the LED chip.

2. The light emitting diode package according to claim 1, wherein the P-electrode and N-electrode of the substrate are extended from the upper surface to the lower surface of the substrate.

3. The light emitting diode package according to claim 1, wherein the conductive material is formed with a trough for locating the LED chip.

4. The light emitting diode package according to claim 1, wherein the lens is formed with a cylinder to mount on the substrate.

5. The light emitting diode package according to claim 1, wherein the N-electrode and P-electrode of the substrate are electrically connected to the LED chip by wires.

6. The light emitting diode package according to claim 1, wherein the conductive material is formed of golden or silver or copper or aluminum or tin or alloy.
